(19) United States
(12) Patent Application Publication
(10) Pub. No.: US 2014/0306240 A1
(43) Pub. Date: Oct. 16, 2014

(54) LIGHT EMITTING DIODE PACKAGE

(71) Applicant: ADVANCED OPTOELECTRONIC TECHNOLOGY, INC., Hsinchu Hsien (TW)

(72) Inventors: HOU-TE LIN, Hukou (TW); YAU-TZU JANG, Hukou (TW); CHAO-HSIUNG CHANG, Hukou (TW); PIN-CHUAN CHEN, Hukou (TW); LUNG-HSIN CHEN, Hukou (TW)

(73) Assignee: ADVANCED OPTOELECTRONIC TECHNOLOGY, INC., Hsinchu Hsien (TW)

(21) Appl. No.: 14/062,829

(22) Filed: Oct. 24, 2013

(30) Foreign Application Priority Data
Apr. 16, 2013 (CN) 2013101312595

(51) Int. Cl. H01L 33/62

(52) U.S. Cl. CPC H01L 33/62
USPC 257/79

(57) ABSTRACT

An exemplary light emitting diode package includes a substrate, a first electrode and a second electrode embedded in the substrate, and a light emitting chip fixed onto the first electrode by first glue. The first electrode has a first barrier member at a periphery of the first glue and below the light emitting chip. The first barrier member obstructs the first glue from spreading toward a side of the first barrier member away from the first glue and the light emitting chip, whereby a contamination by the first glue to an area of the top surface beside the side of the first barrier of the first electrode away from the first glue and the light emitting chip is prevented.

### BACKGROUND

1. Technical Field

This disclosure generally relates to light sources, and particularly to a light-emitting diode package having a barrier member on an electrode to block an overflow of glue on the electrode.

2. Description of Related Art

A typical light emitting diode (LED) package includes a substrate, a first electrode and a second electrode located on the substrate, a light emitting chip located on a top surface the first electrode and electrically connecting with the first and second electrodes by wire bonding.

Generally, a method for mounting the light emitting chip on the top surface of the first electrode includes following steps: providing an amount of glue on the top surface of the first electrode, and then placing the light emitting chip on the glue. The glue securely connects the light emitting chip with the first electrode after the glue is cured.

However, when the light emitting chip is arranged on the glue, the glue is pressed by the light emitting chip and spreads to a periphery of the light emitting chip, whereby the glue occupies a significant area of the top surface of the first electrode. Therefore, the wire bonding area of the first electrode with the light emitting chip thereon is decreased. The decreased wire bonding area can be further decreased if an overflow of the glue on the top surface of first electrode happens, wherein the overflow may occur due to an uneven pressure of the light emitting chip on the glue or an excessive amount of glue being applied to the first electrode. The further decreased bonding area may hinder the light emitting chip from properly wire bonding with the first electrode during the LED package fabrication. Accordingly, the yield rate of the LED package is adversely affected.

What is needed, therefore, is a light emitting diode package which can overcome the above-described shortcoming.

### BRIEF DESCRIPTION OF THE DRAWINGS

FIG. 1 is a top view of a light emitting diode package in accordance with a first embodiment of the present disclosure.

FIG. 2 is a cross-sectional view of the light emitting diode package of FIG. 1, taken along line II-II thereof.

FIG. 3 is a cross-sectional view of a light emitting diode package in accordance with a second embodiment of the present disclosure.

FIG. 4 is a top view of a light emitting diode package in accordance with a third embodiment of the present disclosure.

FIG. 5 is a cross-sectional view of the light emitting diode package of FIG. 4, taken along line V-V thereof.

FIG. 6 is a cross-sectional view of a light emitting diode package in accordance with a fourth embodiment of the present disclosure.

FIG. 7 is a cross-sectional view of a light emitting diode package in accordance with a fifth embodiment of the present disclosure.

FIG. 8 is a cross-sectional view of a light emitting diode package in accordance with a sixth embodiment of the present disclosure.

### DETAILED DESCRIPTION

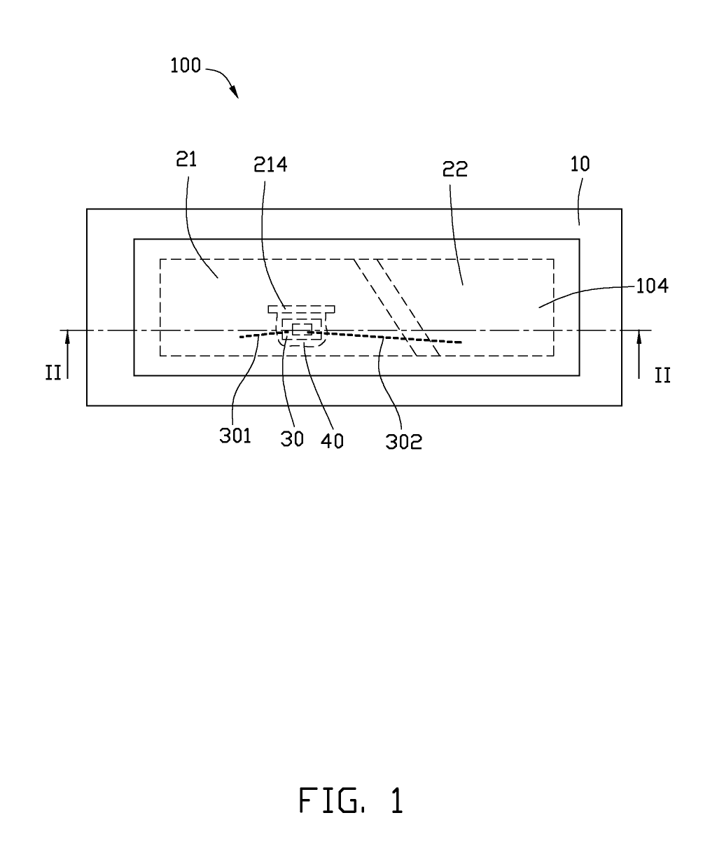

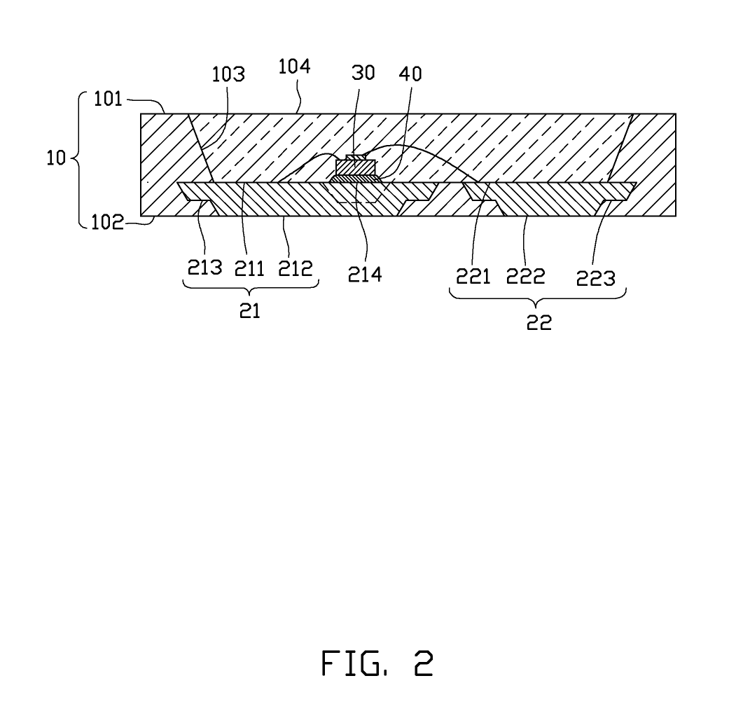

Referring to FIGS. 1-2, a light emitting diode package 100 of a first embodiment in accordance with the present disclosure is provided.

The light emitting diode package 100 includes a substrate 10, a first electrode 21 and a second electrode 22 embedded in the substrate 10, and a light emitting chip 30 mounted on the first electrode 21 and electrically connecting with the first and second electrodes 21,22 respectively via wires 301, 302.

The substrate 10 is made of EMC (Electrical Magnetic Compatibility), PPA (Polyphthalamide), or SMC (Sheet Molding Compound).

The substrate 10 includes a top surface 101 and a bottom surface 102 opposite and parallel to the top surface 101.

A receiving cavity 103 is defined in an upper portion of the substrate 10 to surround the light emitting chip 30 therein. The receiving cavity 103 is recessed from the top surface 101 toward the bottom surface 102. A cross section along a horizontal direction of the substrate 10 is rectangular, and the receiving cavity 103 tapers from a top opening end of the receiving cavity 103 toward a bottom end of the receiving cavity 103. In this embodiment, an encapsulation layer 104 is received in the receiving cavity 103. The encapsulation layer 104 is a mixture of a transparent resin and a plurality of phosphor powders.

The first and second electrodes 21, 22 are spaced from each other, and are received in a lower portion of the substrate 10.

The first electrode 21 includes a first top surface 211, a first bottom surface 212 opposite and parallel to the first top surface 211 and a first lateral surface 213 interconnecting the first top surface 211 and the first bottom surface 212. The second electrode 22 includes a second top surface 221, a second bottom surface 222 opposite and parallel to the second top surface 221, and a second lateral surface 223 interconnecting the second top surface 221 and the second bottom surface 222. In this embodiment, the first lateral surface 213 of the first electrode 21 and the second lateral surface 223 of the second electrode 22 are received in and covered by the substrate 10. Each of the lateral surfaces 213, 223 is zigzag.

A thickness of the first electrode 21 equals a thickness of the second electrode 22. The first electrode 21 and the second electrode 22 each have a thickness less than a height of the substrate 10. In this embodiment, the first top surface 211 of the first electrode 21 and the second top surface 221 of the second electrode 22 are coplanar with each other, and are coplanar with the bottom end of the receiving cavity 103 of the substrate 10. The first bottom surface 212 of the first electrode 21 and the second bottom surface 222 of the second electrode 22 are coplanar with and exposed out of the bottom surface 102 of the substrate 10.

The light emitting chip 30 is located at the bottom of the receiving cavity 103, and is fixed onto the first top surface 211 of the first electrode 21 by first glue 40. In this embodiment, the first glue 40 is made of electrically insulating material.

A first barrier member 214 is defined in/on the first electrode 21. The first barrier member 214 is below the light emitting chip 30 and located at a periphery of the first glue 40. In the first embodiment, the first barrier member 214 is a receiving slot defined in the first top surface 211 of the first electrode 21.

Preferably, the first barrier member 214 is located close to the light emitting chip 30 and the first glue 40 to receive some first glue 40 therein if the first glue 40 overflows during the mounting of the light emitting chip 30 to the first top surface 211 of the first electrode 21 by bringing the light emitting chip 30 to press on the first glue 40. The first barrier member 214 is recessed from the first top surface 211 of the first electrode 21 toward the first bottom surface 212 of the first electrode 21. A depth of the first barrier member 214 is less than a thickness of the first electrode 21; that is, the first barrier member 214 does not extend through the first electrode 21 along a thickness direction of the first electrode 21.

The first barrier member 214 is an elongated rectangular receiving slot, and a length of the opening of the first barrier member 214 along a longitudinal direction of the first electrode 21 is less than a length of the first electrode 21, but is larger than a width of the first glue 40 along the longitudinal direction of the first electrode 21 after the light emitting chip 30 is pressed onto the first glue 40.

The first barrier member 214 tapers from the top opening end toward a bottom end. In this embodiment, a cross section of the first barrier member 214 along a horizontal direction is rectangular. The first barrier member 214 is straight. Alternatively, the first barrier member 214 may be curved.

In the first embodiment, when the light emitting chip 30 is arranged on the first glue 40, the first glue 40 is pressed by the light emitting chip 30 to spread to a periphery of the light emitting chip 30. Because of the first barrier member 214, some part of the first glue 40 flowing toward the first barrier member 214 flows into the receiving slot, rather than spreading toward other side of the first barrier member 214 to occupy an area of the first top surface 211 of the first electrode 21 at the other side of the first barrier member 214. Therefore, more area of the first top surface 211 of the first electrode 21 can be used as a wire bonding area.

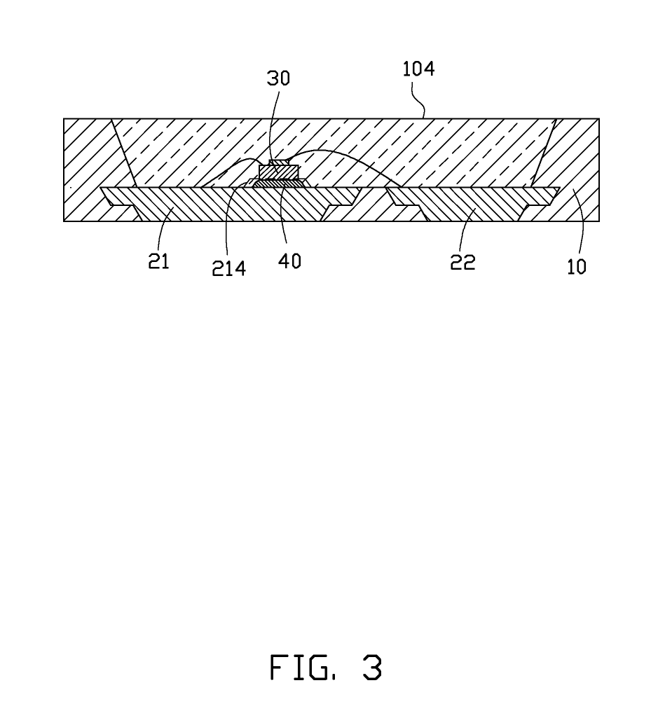

Referring to FIG. 3, in a second embodiment, the first barrier member 214 is a blocking wall below the light emitting chip 30. The first barrier member 214 is formed at a periphery of the first glue 40.

The first barrier member 214 extends upwardly from the first top surface 211 of the first electrode 21. A height of the first barrier member 214 is larger than a thickness of the first glue 40 after the light emitting chip 30 is pressed onto the first glue 40. A length of the first barrier member 214 along the longitudinal direction of the first electrode 21 is larger than a width of the first glue 40 along the longitudinal direction of the first electrode 21. In this embodiment, a front side view of the first barrier member 214 is trapezoid, and the length of the barrier member 214 along the longitudinal direction of the first electrode 21 gradually decreases from a bottom end of the barrier 214 connecting with the first electrode 21 toward a top end thereof far away from the first electrode 21. A width of the first barrier member 214 along a transverse direction of the first electrode 21 is less than a width of the light emitting chip 30. The barrier member 214 is separably formed from the first electrode 21 and then attached to the first electrode 21. Alternatively, the first barrier member 214 is formed with the first electrode 21 as a single piece.

And when the light emitting chip 30 is arranged on the first glue 40, the first glue 40 is pressed by the light emitting chip 30 to spread to the periphery of the light emitting chip 30. Because of the first barrier member 214, the glue 40 is obstruct by the first barrier member 214, such that, the glue 40 can not flow to the other side of the first barrier member 214 to occupy the first top surface 211 of the first electrode 21 at the other side of the first barrier member 214, whereby more area of the top surface of the first electrode 21 can be used as a wire bonding area.

Furthermore, because the first barrier member 214 is below the light emitting chip 30, light emitted from the light emitting chip 30 is not blocked by the first barrier member 214, which maintains a high light emitting efficiency of the light emitting chip 30.

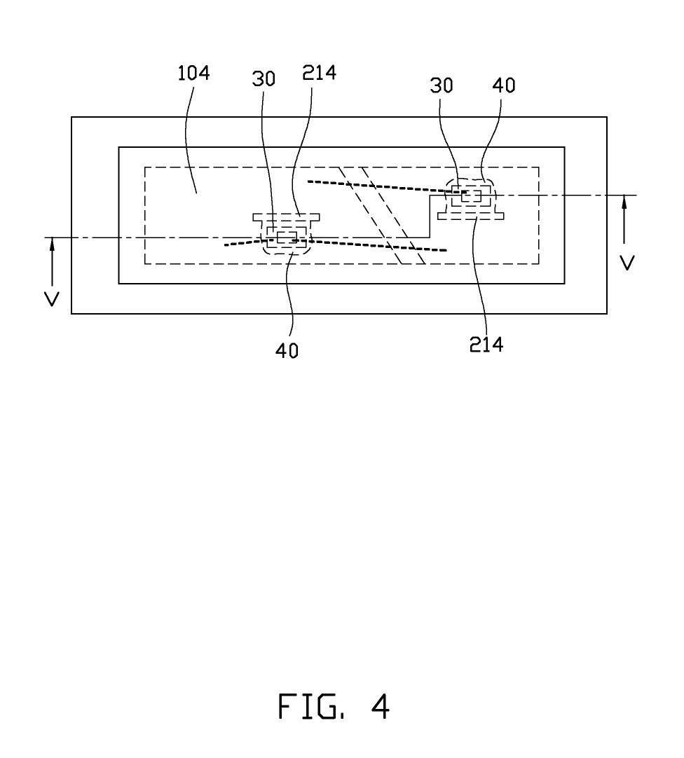

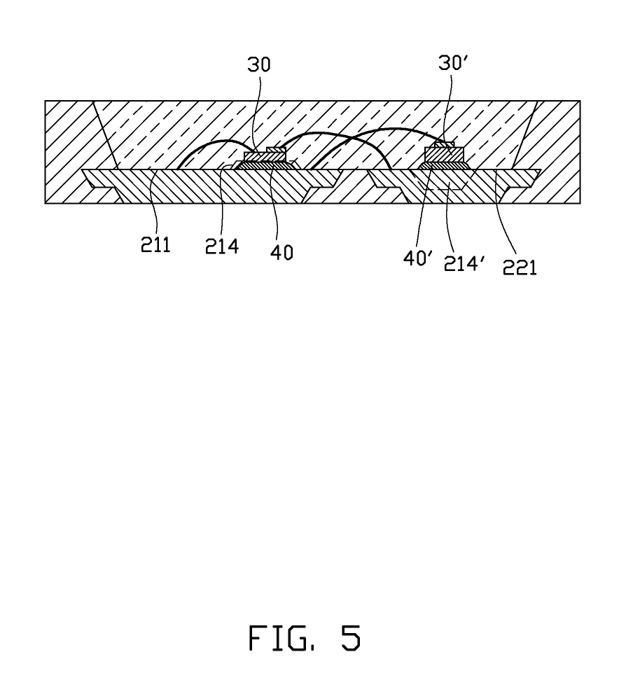

Referring to FIGS. 4-5, in a third embodiment, a zener diode 30′ is located on the second top surface 221 of the second electrode 22 and electrically connecting with the first and second electrode 21, 22 by wires respectively.

The zener diode 30′ is in inverse parallel connection with the light emitting chip 30 to protect the light emitting chip 30 from ESD (Electrostatic Discharge). The zener diode 30′ is fixed onto the second top surface 221 of the second electrode 22 by second glue 40′. The second glue 40′ is made of electrically conductive materials.

In this embodiment, a second barrier member 214′ is defined in/on the second electrode 22. The second barrier member 214′ is located at a periphery of the zener diode 30′.

The second barrier member second 214′ has a same configuration with the first barrier member 214. The second barrier member 214′ is used to obstruct the second glue 40′ from spreading toward other side of the second barrier member 214′ to occupy the second top surface 221 of the second electrode 22 at the other side of the second barrier member 214′.

In the third embodiment, the first barrier member 214 on the first electrode 21 is a blocking wall, and the second barrier member 214 defined in the second electrode 22 is an elongated rectangular receiving slot. A depth of the second barrier member 214′ is less than the thickness of the second electrode 22; a length of the second barrier member 214′ is larger than a width of the second glue 40′, but less than a length of the second electrode 22.

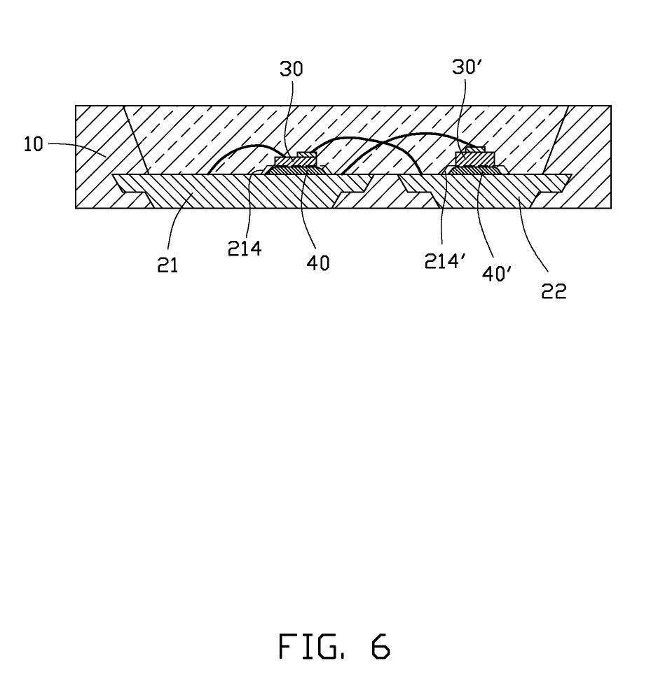

Alternatively, the second barrier member 214′ may be a blocking wall (shown in FIG. 6) in a fourth embodiment. A height of the second barrier member 214′ is larger than a thickness of the second glue 40′, and a length of the second barrier member 214′ along the longitudinal direction of the second electrode 22 is larger than a width of the second glue 40′ along the longitudinal direction of the second electrode 22, after the zener diode 30′ is brought press on the second glue 40′.

When the zener diode 30′ is mounted on the second top surface 221 of the second electrode 22, the second glue 40′ is pressed to spread to a periphery of the zener diode 30′. The second barrier member 214′ obstructs the second glue 40′ from spreading further toward the other side of the second barrier member 214′ away from the zener diode 30′ to occupy the second top surface 221 of the second electrode 22 at the other side of the second barrier member 214′. Such that, more area of the second top surface 221 of the second electrode 22 can be used as a wire bonding area.

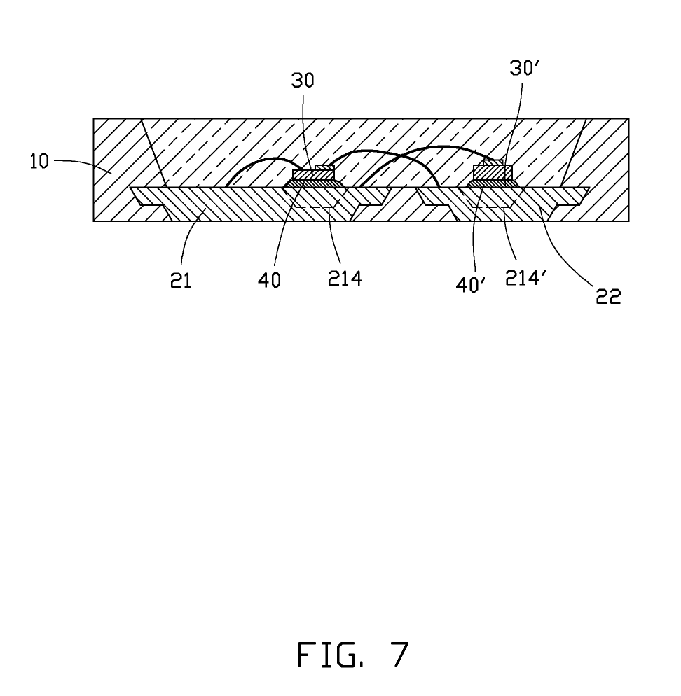

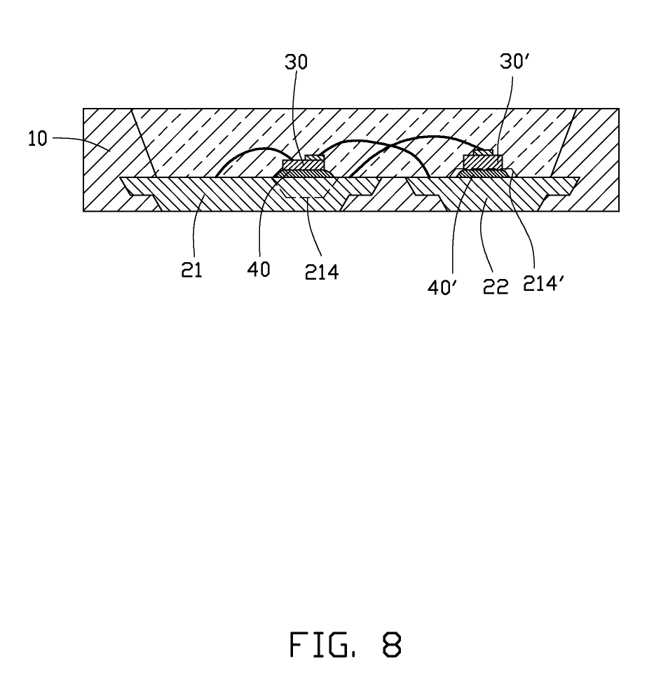

Referring to FIG. 7, in a fifth embodiment, the first barrier member 214 is a receiving slot defined in the first electrode 21, and the second barrier member 214′ is a receiving slot defined in the second electrode 22. Alternatively, the second barrier member 214′ may be a blocking wall formed on the second top surface 221 of the second electrode 22 (shown in FIG. 8) in a sixth embodiment.

In this disclosure, because the light emitting diode package has a first barrier member 214 (or a second barrier member 214′) to obstruct the first glue 40 (or the second glue 40′) from spreading toward the other side of the first barrier member 214 (or the second barrier member 214′), more wire bonding area of the first and second electrodes 21, 22 can be provided.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting diode package, comprising:
a substrate;
a first electrode and a second electrode spaced from each other and embedded in the substrate; and
a light emitting chip fixed onto the first electrode by first glue under the light emitting chip, and the light emitting chip electrically connecting with the first electrode and the second electrode by two wires respectively;
wherein the first electrode has a first barrier member having a side adjacent to the first glue and the light emitting chip, the first barrier member is located below the light emitting chip, and the first barrier member is formed to obstruct the first glue from spreading towards another side of the first barrier member away from the light emitting chip and the first glue.

2. The light emitting diode package of claim 1, wherein the first barrier member is a receiving slot defined in a periphery of the first glue to receive the first glue flowing toward the first barrier member.

3. The light emitting diode package of claim 2, wherein the receiving slot is an elongated rectangular slot, and a depth of the receiving slot is less than a thickness of the first electrode.

4. The light emitting diode package of claim 3, wherein a length of an opening of the receiving slot is larger than a width of the glue, and is less than a length of the first electrode.

5. The light emitting diode package of claim 2 further comprising a zener diode fixed onto the second electrode by second glue under the zener diode, and the zener diode electrically connecting with the first and second electrodes, wherein the zener diode is electrically connected with the first electrode by a wire.

6. The light emitting diode package of claim 5, wherein the zener diode is in inverse parallel connection with the light emitting diode.

7. The light emitting diode package of claim 5, wherein the first glue is made of electrically insulating material and the second glue is made of electrically conductive material.

8. The light emitting diode package of claim 5, wherein the second electrode has a second barrier member to obstruct the second glue from spreading toward a side of the second barrier member away from the zener diode.

9. The light emitting diode package of claim 8, wherein the second barrier member is a blocking wall located at a periphery of the second glue.

10. The light emitting diode package of claim 8, wherein the second barrier member is a receiving slot defined in the second electrode and located at a periphery of the second glue, and a depth of the second barrier member is less than a thickness of the second electrode.

11. The light emitting diode package of claim 10, wherein a length of the second barrier member is larger than a width of the second glue, and the length of the second barrier member is less than a length of the second electrode.

12. The light emitting diode package of claim 1, wherein the first barrier member is a blocking wall located at a periphery of the first glue.

13. The light emitting diode package of claim 12, wherein a length of the first barrier member is larger than a width of the first glue.

14. The light emitting diode package of claim 13, wherein a height of the first barrier member is larger than a thickness of the first glue.

15. The light emitting diode package of claim 12 further comprising a zener diode fixed onto the second electrode by second glue under the zener diode, and the second electrode has a second barrier member to obstruct the second glue from spreading toward a side of the second barrier member away from the zener diode.

16. The light emitting diode package of claim 15, wherein the second barrier member is a receiving slot defined in the second electrode and located at a periphery of the second glue.

17. The light emitting diode package of claim 15, wherein the second barrier member is a blocking wall formed on the second electrode at a periphery of the second glue.

18. The light emitting diode package of claim 17, wherein a height of the second barrier member is larger than a thickness of the second glue.

19. The light emitting diode package of claim 15, wherein the first glue is made of electrically insulating material and the second glue is made of electrically conductive material.
